(19) United States
(12) Patent Application Publication
(10) Pub. No.: US 2020/0310573 A1
(43) Pub. Date: Oct. 1, 2020

(54) TOUCH DISPLAY, ASSOCIATED DRIVER INTEGRATED CIRCUIT AND TOUCH DISPLAY PANEL THEREOF

(71) Applicant: INT TECH CO., LTD., Hsinchu County (TW)

(72) Inventor: KUO-CHENG HSU, TAICHUNG CITY (TW)

(21) Appl. No.: 16/364,986

(22) Filed: Mar. 26, 2019

(51) Int. Cl. G06F 3/041; H01L 27/32; G06F 3/044; G06K 9/00

(52) U.S. Cl. CPC G06F 3/0412; H01L 27/323; G06K 9/0002; G06F 3/044; G06F 3/0416; H01L 27/3244

(57) ABSTRACT

A touch display, includes: a driver integrated circuit (IC) and a touch display panel. The driver IC is arranged to selectively control the touch display to operate in a touch mode or a fingerprint mode. The touch display panel includes a first section and a second section. The first section includes a plurality of first electrodes, wherein the first section is arranged to sense a touch maneuver of a user. The second section includes a plurality of second electrodes, and a bottom surface of the second section and a bottom surface of the first section are coplanar. The second section is arranged to sense a biometric of the user when the touch display operates in the biometric mode, and sense the touch maneuver of the user when the touch display operates in the touch mode.

### BACKGROUND

Conventionally, a fingerprint recognition system of a mobile device is installed separately from touch display panels of the mobile device. Therefore, in order to save room for the fingerprint recognition system, it is difficult to achieve full screen mobile device.

### SUMMARY OF THE INVENTION

One of the objectives of the present disclosure is to provide a touch display, an associated driver integrated circuit and a touch display panel to solve the aforementioned problem.

According to an embodiment of the present disclosure, a touch display is disclosed. The touch display comprises a driver integrated circuit (IC) and a touch display panel. The driver IC is arranged to selectively control the touch display to operate in touch mode or fingerprint mode. The touch display panel includes a first section and a second section. The first section includes a plurality of first electrodes, wherein the first section is arranged to sense a touch maneuver of a user. The second section includes a plurality of second electrodes, and a bottom surface of the second section and a bottom surface of the first section are coplanar. The second section is arranged to sense a biometric of the user when the touch display operates in the biometric mode, and sense the touch maneuver of the user when the touch display operates in touch mode.

According to an embodiment of the present disclosure, a driver integrated circuit (IC) of a touch display is disclosed. The touch display includes a touch display panel which includes a plurality of first electrodes and a plurality of second electrodes, and a size of each second electrode is smaller than that of each first electrode. Bottom surfaces of the plurality of second electrodes and bottom surfaces of the plurality of first electrodes are coplanar. The driver IC is arranged to couple each second electrode to a common voltage source when the touch display operates in a biometric mode to sense a biometric of a user.

According to an embodiment of the present disclosure, a touch display panel is disclosed. The touch display panel includes an illuminate layer, a plurality of electrode in a horizontally different tier from the illuminate layer and a circuit. The illuminate layer is formed on a substrate. The circuit is electrically coupled to the electrodes and used to switch a portion of the electrodes between a mode for recognition to a touch maneuver of a user and a mode for recognition to a biometrics of the user.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG.1 is a diagram illustrating a touch display according to an embodiment of the present disclosure.

FIG. 2 is a diagram illustrating a manufacturing process of a touch display panel according to an embodiment of the present disclosure.

FIG. 3 is a diagram illustrating a manufacturing process of a touch display panel according to another embodiment of the present disclosure.

FIG. 4 is a diagram illustrating a touch display according to a first embodiment of the present disclosure.

FIG. 5 is a diagram illustrating a touch display according to a second embodiment of the present disclosure.

FIG. 6 is a diagram illustrating a touch display according to a third embodiment of the present disclosure.

FIG. 7 is a diagram illustrating a touch display according to a fourth embodiment of the present disclosure.

FIG. 8 is flowchart illustrating a driving method of a touch display according to an embodiment of the present disclosure.

FIG. 9 is flowchart illustrating a driving method of a touch display according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a. relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

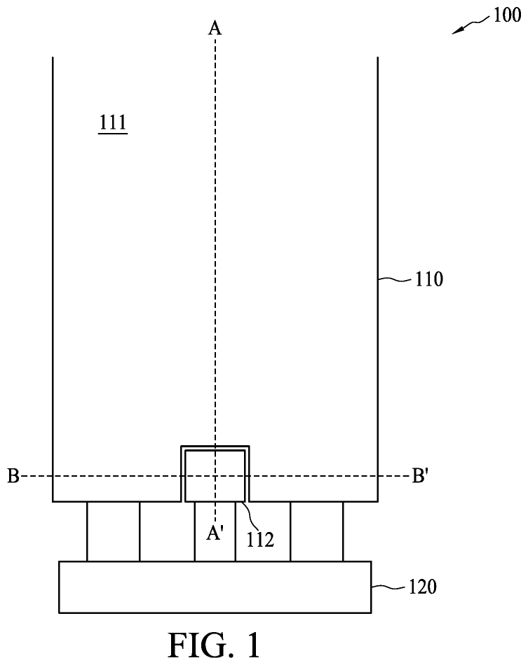

FIG. 1 is a diagram illustrating a touch display 100 according to an embodiment of the present disclsore. As shown in FIG. 1, the touch display 100 includes a touch display panel 110 and a driver integrated circuit (IC) 120. The touch display panel 110 includes a first section 111 and a second section 112, wherein each of the first section 111 and the second section 112 includes a plurality of electrodes. In this embodiment, the touch display 100 can be applied to mobile device like smart phone, tablet, etc. Based on the usage of mobile device in practice, the driver IC 120 controls the touch display 100 to selectively operate in touch mode or biometric mode. Accordingly, the function of the second section 112 of the touch display panel 110 is adjusted by the driver IC 120. For example, when a user of the touch display 100 is broswing the interna, the driver IC 120 controls the touch display 100 to operate in touch mode to facilitate the slide operation. When the user is online-shopping and the identity needs to be verified, the driver IC 120 controls the touch display 100 to operate in the biometric mode to sense the biometric of the user to complete the transaction.

More specifically, when the touch display 100 operates in the touch mode, the second section 112 is arranged to sense a touch maneuver of a user of the touch display 100. When the touch display 100 operates in the biometric mode, the second section 112 is arranged to sense a biometric such as a fingerprint of the user. On the other hand, the first section 111 is arranged to sense the touch maneuver of the user.

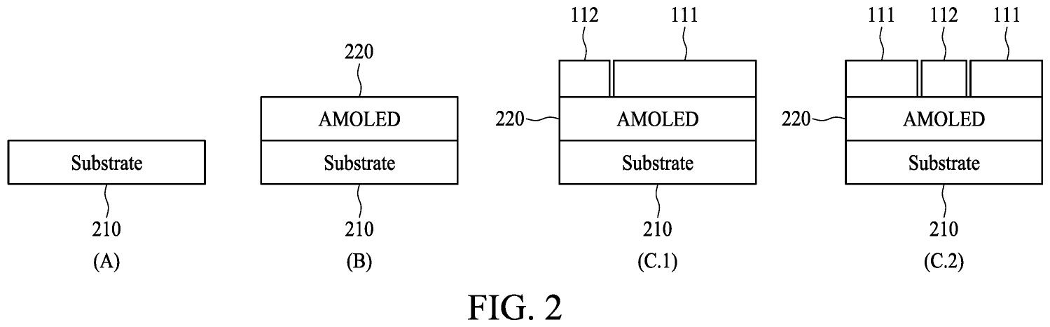

FIG. 2 is a diagram illustrating a manufacturing process of the touch display panel 110. In the sub-diagram (A) of FIG. 2, a substrate 210 is received. In the sub-diagram (B) of FIG. 2, an illuminating layer 220 is formed on the substrate 210. In this embodiment, the illuminating layer 220 includes active-matrix organic light-emitting diodes (AMOLEDs). In the sub-diagrams (C.1) and (C.2) of FIG. 2, the first section 111 and the second section 112 are formed on a top surface of the illuminating layer 220, and bottom surfaces of the first section 111 and the second section 112 are coplanar. The sub-diagram (C.1) of FIG. 2 illustrates a cross-sectional perspective along the line A-A′ in FIG. 1 while the sub-diagram (C.2) of FIG. 2 illustrates a cross-sectional perspective along the line B-B′ in FIG. 1. It should be noted that there may be an isolation material (not shown in FIG. 2) located between the first section 111 and the second section 112.

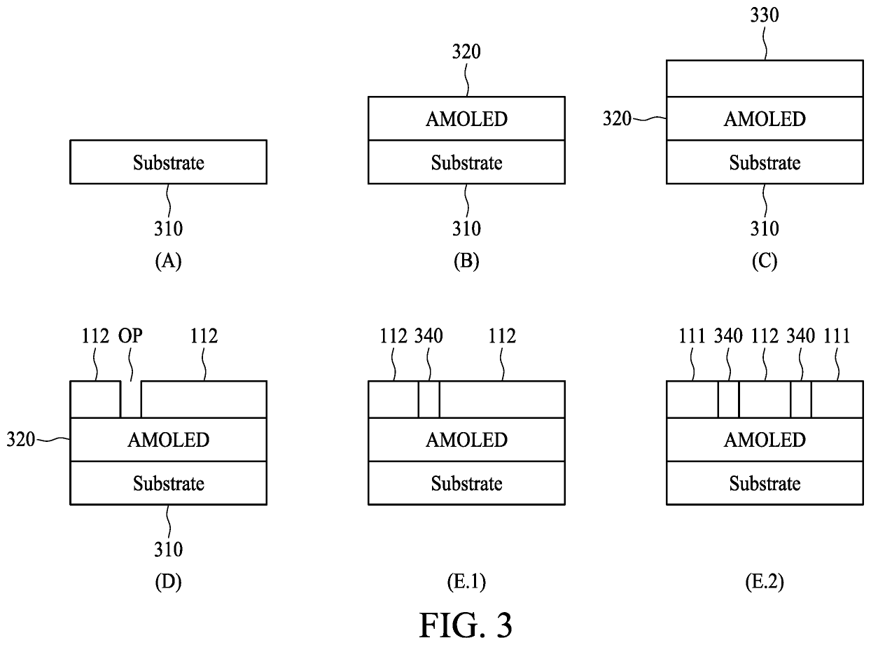

FIG. 3 is a diagram illustrating a manufacturing process of the touch display panel 110. In the sub-diagram (A) of FIG. 3, a substrate 310 is received. In the sub-diagram (B) of FIG. 3, an illuminating layer 320 is formed on the substrate 310. In this embodiment, the illuminating layer 320 includes AMOLEDs, and a dielectric layer on the AMOLEDs. In the sub-diagram (C) of FIG. 3, a conductive layer 330 is formed on the illuminating layer 320. In some embodiments, the conductive layer 330 may be implemented by Indium Tin Oxide (ITO) for forming the plurality of electrodes in the first section 111 and the second section 112. In the sub-diagram (D) of FIG. 3, a photolithography operation is performed on the conductive layer 330 to form the first section 111 and the second section 112. The patterned conductive layer includes openings such like opening OP exposing the top surface of the illuminating layer 320. In the sub-diagrams (E.1) and (E.2) of FIG. 3, an isolation material configured as a cap layer 340 is filled in the opening OP to form a patterned cap layer for separating the first section 111 and the second section 112. Bottom surfaces of the first section 111, the second section 112, and the cap layer 340 are coplanar. The sub-diagram (E.1) of FIG. 3 illustrates a cross-sectional perspective along the line A-A′ in FIG. 1, while the sub-diagram (E.2) of FIG. 3 illustrates a cross-sectional perspective along the line B-B′ in FIG, 1. It should be noted that the thickness of the cap layer filleded between the first section 111 and the second section 112 is only for illustrative purpose.

In other embodiments, the steps shown in FIG, 3 can be adjusted. For example, after the step (B), the cap layer 340 is formed on the illuminating layer 320 first. Next, a photolithography operation is performed on the cap layer 340. Therefore, a patterned cap layer 340 including openings is provided. Finally, the conductive layer 330 is electroplated in the openings to form the first section 111 and the second section 112.

In the embodiments of FIGS. 2 and 3, the first section 111 and the second section 112 are formed in the same layer. With such configurations, the biometric sensing function and the touch sensing function are implemented in the same layer which reduce the layers of the touch display panel 110 and consume less area.

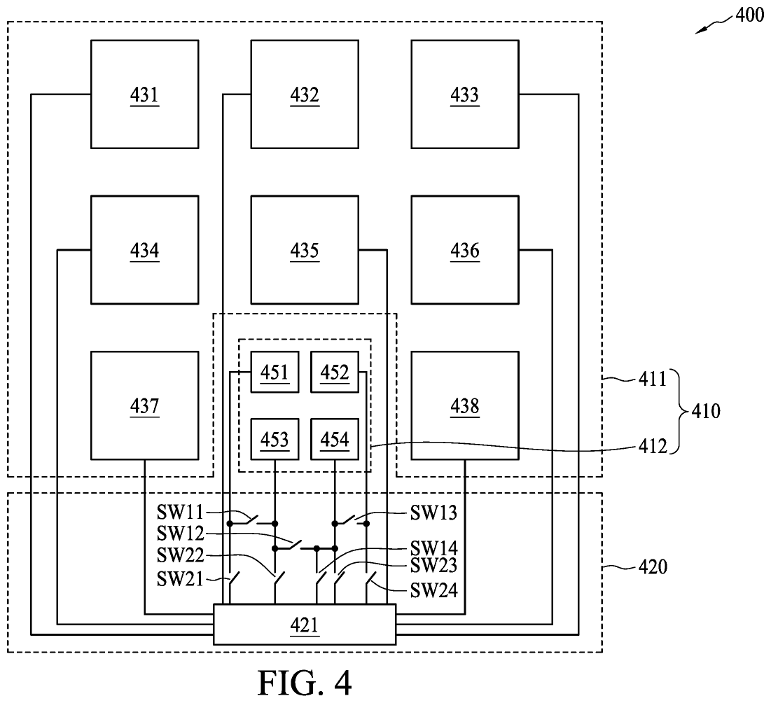

FIG. 4 is a diagram illustrating a touch display 400 according to a first embodiment of the present disclosure. The touch display 400 can be adapted to implement the touch display 100 mentioned in FIG. 1. As shown in FIG. 4, the touch display 400 includes a touch display panel 410 and a driver IC 420, wherein the touch display panel 410 includes a first section 411 and a second section 412. The first section 411 includes electrodes 431 to 438, and the second section 412 includes electrodes 451 to 454. wherein each electrode in the second section 412 is smaller than each electrode in the first section 411 to facilitate the biometric sensing function. It should be noted that the number of electrodes included in the first section 411 and the second section 412 are only for illustrative purpose. In some embodiments, more columns and rows of electrodes are included in the first section 411 and the second section 412 to accurately sense the touch maneuver and the biometric of the user. Furthermore, the shape of each electrode is only for illustrative purpose, and it should not be limited by the present disclosure.

Each electrode in the first section 411 and the second section 412 is coupled to the driver IC 420. In this embodiment, the driver IC 420 includes a common voltage source 421, first switches SW11 to SW14 and second switches SW21 to SW24. The switch statuses of the first switches SW11 to SW14 and the second switches SW21 to SW24 are adjusted according to the operating mode of the touch display 400. It should be noted that the driver IC 420 may include more circuits and modules therein, however, only those pertinent to the present disclosure are shown in FIG. 4.

More specifically, when the driver IC 420 controls the touch display 400 to operate in touch mode, the driver IC 420 transmits the common voltage generated from the common voltage source 421 to each of the electrodes 431 to 438. In addition, the first switches SW11 to SW14 are activated while the second switches SW21 to SW24 are deactivated. With such configurations, the electrodes 451 to 454 are short circuited to form an intact electrode similar to each of the electrodes 431 to 438. The driver IC 420 transmits the common voltage generated from the common voltage source 421 to the electrodes 451 to 454. The touch maneuver of the user can be detected by sensing the self-capacitor formed between each electrode and the around terminal.

When the driver IC 420 controls the touch display 400 to operate in the biometric mode, the driver IC 420 transmits the common voltage generated from the common voltage source 421 to each of the electrodes 431 to 438 to maintain the touch sensing function of the first section 411. In addition, the first switches SW11 to SW14 are deactivated while the second switches SW21 to SW24 are activated. With such configurations, each of the electrodes 451 to 454 is considered as an isolated electrode. The driver IC 420 transmits the common voltage generated from the common voltage source 421 to each of the electrodes 451 to 454. The touch maneuver can stilled be sensed by the electrodes 431 to 438 while the biometric such as a fingerprint of the user can be sense by the electrodes 451 to 454.

In this embodiment, the electrodes 431 to 438 and 451 to 454 connect to the driver IC 420 by routings. As shown in FIG. 4, the routings are implemented in the same layer with the electrodes 431 to 438 and 451 to 454. However, to save more room for routing, the space between two electrodes shown in FIG. 4 is enlarged due to the design rules of the adapted manufacturing process of the touch display panel 410.

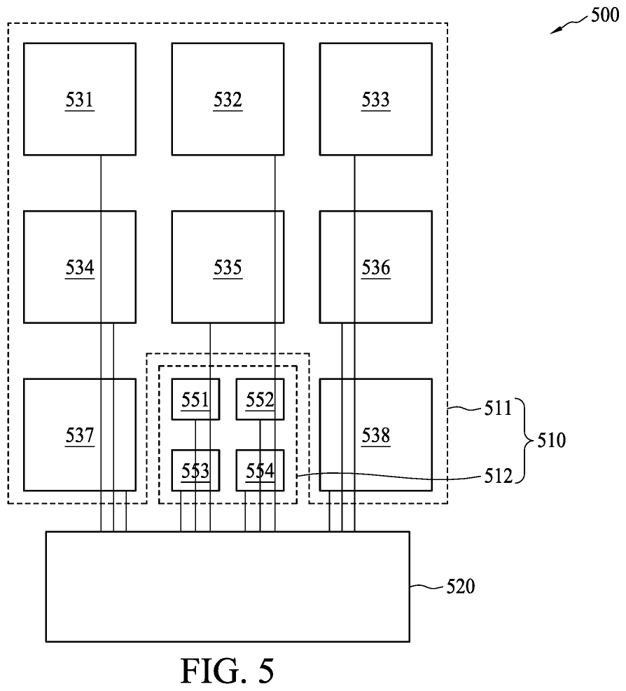

FIG. 5 is a diagram illustrating a touch display 500 according to a second embodiment of the present disclosure. The touch display 500 includes a touch display panel 510 and the driver IC 520, wherein the touch display panel 510 and the driver IC 520 are similar to those described in FIG. 4 except the connections between each electrode and the driver IC 520 is implemented in different layer from the electrodes. More specifically, the connections are implemented via contact vias. The room saved for routing between electrodes in FIG. 4 is accordingly reduced. Therefore, the electrodes are formed closer, and more electrodes can be formed in the touch display panel 110. The resolution of the touch display panel 110 is accordingly increased.

More specifically, when the driver IC 520 controls the touch display 500 to operate in the touch mode, the driver IC 520 transmits the common voltage generated from a common voltage source in the driver IC 520 to each of the electrodes 531 to 538. In addition, first switches SW11 to SW14 as described in FIG. 4 are activated while second switches SW21 to SW24 as described in FIG. 4 are deactivated. With such configurations, the electrodes 551 to 554 are short circuited to form an intact electrode similar to each of the electrodes 531 to 538. The driver IC 520 transmits the common voltage generated from the common voltage source to the electrodes 551 to 554. The touch maneuver of the user can be detected by sensing the self-capacitor formed between each electrode and the ground terminal.

When the driver IC 520 controls the touch display 500 to operate in the biometric mode, the driver IC 520 transmits the common voltage generated from the common voltage source to each of the electrodes 531 to 538 to maintain the touch sensing function of the first section 511. In addition, the first switches SW11 to SW14 as described in FIG. 4 are deactivated while the second switches SW21 to SW24 as described in FIG. 4 are activated. With such configurations, each of the electrodes 551 to 554 is considered as an isolated electrode. The driver IC 520 transmits the common voltage generated from the common voltage source to each of the electrodes 551 to 554. The touch maneuver can stilled be sensed by the electrodes 531 to 538 while the biometric such as fingerprint of the user can be sense by the electrode 551 to 554.

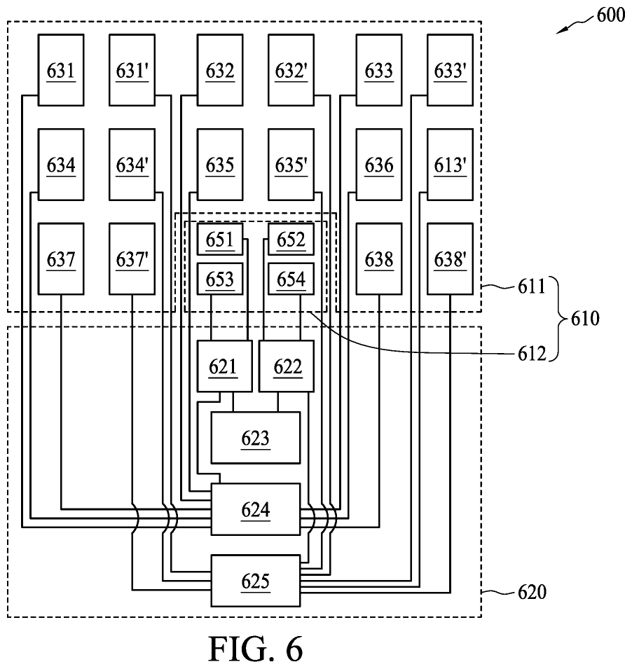

FIG. 6 is a diagram illustrating a touch display 600 according to a third embodiment of the present disclosure. The touch display 600 can be adapted to implement the touch display 100 mentioned in FIG. 1. As shown in FIG. 6, the touch display 600 includes a touch display panel 610 and a driver IC 620. wherein the touch display panel 610 includes a first section 611 and a second section 612. The first section 611 includes transmitter electrodes 631 to 638 and corresponding receiver electrode 631′ to 638′, and the second section 612 includes electrodes 651 to 654, wherein each electrode in the second section 612 is smaller than each electrode in the first section 611 to facilitate the biometric sensing function. It should be noted that the number of electrodes included in the first section 611 and the second section 612 are only for illustrative purpose. In sonic embodiments, more columns and rows of electrodes are included in the first section 611 and the second section 612 to accurately sense the touch maneuver and the biometric of the user. Furthermore, the shape of each electrode is only for illustrative purpose, and it should not be limited by the present disclosure.

In this embodiment, the driver IC 620 includes switch circuits 621 and 622, a common voltage source 623, a transmitter circuit 624 and a receiver circuit 625. It should be noted that the driver IC 620 may include more circuits and modules therein, however, only those pertinent to the present disclosure are shown in FIG. 6. The transmitter circuit 624 is arranged to transmit a transmitter signal to the transmitter electrodes 631 to 638, and the receiver circuit 622 is arranged to detect receiver signals carried on the receiver electrodes 631′ to 638′.

More specifically, when the driver IC 620 controls the touch display 600 to operate in the touch mode, the transmitter circuit 624 transmits the transmitter signal to each of the transmitter electrodes 631 to 638. In addition, the switch circuit 621 couples the electrodes 651 and 653 together, i.e., makes the electrodes 651 and 653 short-circuit, to the transmitter circuit 624 to receive the transmitter signal, and couples the electrodes 652 and 654 together, i.e., makes the electrodes 652 and 654 short-circuit to the receiver circuit 625. With such configurations, the electrodes 651 and 653 are short circuited and receive the transmitter signal to form an intact electrode similar to each of the transmitter electrodes 631 to 638. On the other hand, the electrodes 652 and 654 are short circuited and coupled to receiver circuit 625 to form an intact electrode similar to each of the receiver electrode 631′ to 638′. The touch maneuver of the user can be detected by sensing the mutual-capacitor formed between each transmitter electrode and the corresponding receive electrode.

When the driver IC 620 controls the touch display 600 to operate in the biometric mode, the switch circuit 621 couples each of the electrodes 651 and 653 separately to the common voltage source 623, and the switch circuit 622 couples each of the electrodes 652 and 654 separately to the common voltage source 623. With such configurations, each of the electrodes 651 to 654 is considered as an isolated electrode. The driver IC 620 transmits the common voltage generated from the common voltage source 623 to each of the electrodes 651 to 654. The touch maneuver can stilled be sensed by the transmitter electrodes 631 to 638 while the biometric such as a fingerprint of the user can be sense by the electrode 651 to 654.

As mentioned above, to save more room for routing, the space between two electrodes shown in FIG. 6 is enlarged due to the design rules of the adapted manufacturing process of the touch display panel 610.

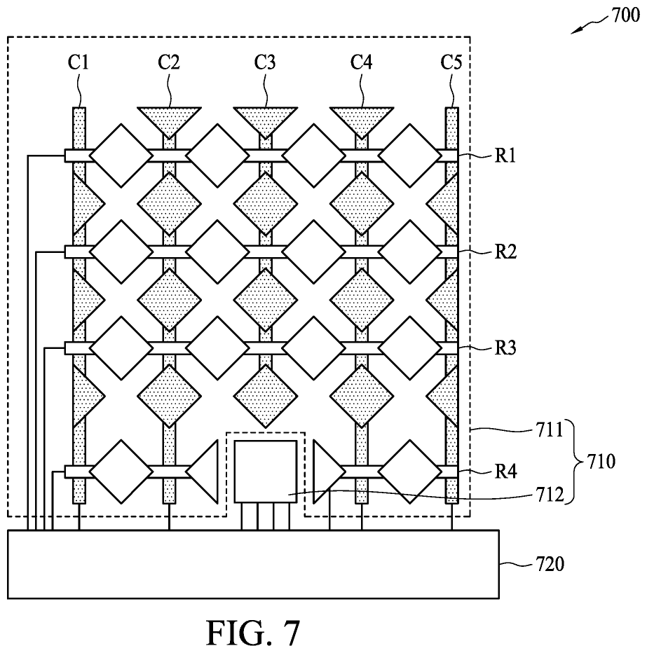

FIG. 7 is a diagram illustrating a touch display 700 according to a fourth embodiment of the present disclosure. The touch display 700 includes a touch display panel 710 and the driver IC 720, wherein the touch display panel 710 includes a first section 711 and a second section 712. The touch display panel 710 and the driver IC 720 are similar to those described in FIG. 6 except the pattern of the first section 711 in the touch display panel 710. In this embodiment, the first section 711 includes columns of electrodes (e.g., the columns C1 to C5) and rows of electrodes (e.g., the rows R1 to R4). The shape of the electrodes included in the first section 111 is diamond-shape, and the columns C1 to C5 of electrodes are configured as the transmitter electrodes while the rows R1 to R4 of electrode are configured as the receiver electrodes. Alternatively, the columns C1 to C5 of electrodes are configured as the receiver electrodes while the rows R1 to R4 of electrode are configured as the transmitter electrodes. It should be noted that the numbers of columns and rows of electrodes in the first section 111 are only for illustrative purpose, and it should not be limited in the present disclosure.

In each row, the electrodes are connected via contact vias which located in different layer from the electrodes. In each column, the electrodes are connected via routings which located in same layer as the electrodes. Alternatively, in each row, the electrodes are connected via routing which located in same layer as the electrodes. In each row, the electrodes are connected via contact vias which located in different layer from the electrodes.

With the driver IC 720 identical to that described in the embodiment of FIG. 6, when the driver IC 720 controls the touch display system 700 to operate in the touch mode, a transmitter circuit as same as the transmitter circuit 624 transmits the transmitter signal to the transmitter electrodes while a receiver circuit as same as the receiver circuit 625 receives the receiver signals from the receiver signals. The touch maneuver of the user can be detected by sensing the mutual-capacitor formed between every intersect points between each row and column. Likewise, with the second section 712 as same as that described in the embodiments of FIG, 6. the second section 712 has the functions of sensing touch maneuver and the biometric of the user.

With the patterned first section 711 depicted in FIG. 7. the room saved for routing between electrodes in FIG. 6 are reduced. Therefore, the electrodes are formed closer, and more electrodes can be formed in the touch display panel 110. The resolution of the touch display panel 710 is accordingly increased.

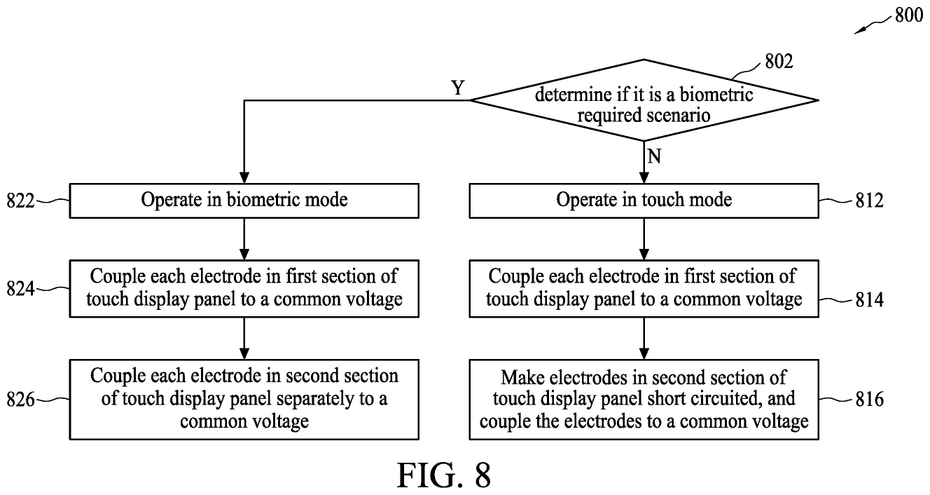

FIG. 8 is a flowchart illustrating a driving method 800 of a touch display according to an embodiment of the present disclosure. Provided that the results are substantially the same, the steps shown in FIG. 8 are not required to be executed in the exact order. The method 800 is summarized as follow.
Step 802: determine if it is a biometric required scenario, if yes, go to step 822; otherwise, go to step 812.
For example, when the user is online-shopping and the identify needs to be verified, the touch display is controlled to operate in the biometric mode to sense the biometric of the user to complete the transaction.
Step 812: operate in a touch mode.
Step 814: couple each electrode in a first section of a touch display panel to a common voltage.
Step 816: make electrodes in second section of touch display panel short circuited, and couple the electrodes to a common voltage.

With such configurations, the touch maneuver of the user can be detected by sensing the self-capacitor formed between each electrode and the ground terminal.
Step 822: operate in biometric mode.
Step 824: couple each electrode in the first section of the touch display panel to a common voltage.
Step 826: couple each electrode in a second section of the touch display panel separately to a common voltage

With such configurations, the touch maneuver of the user can stilled be sensed by the first section while the biometric of the user such like the fingerprint can be sensed by the second section.

Those skilled in the art should readily understand the detail of the driving method 800 after reading the embodiments of FIGS. 4 and 5. The detailed description is omitted here for brevity.

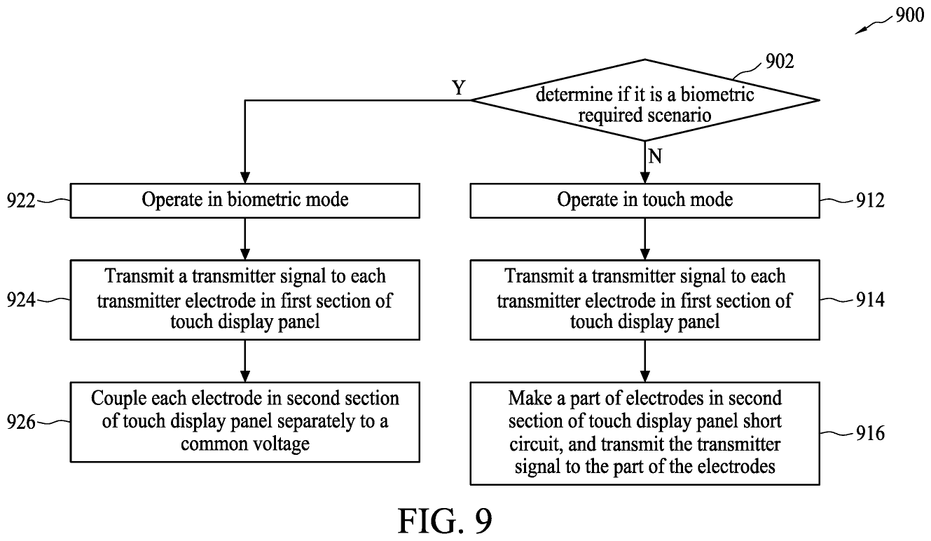

FIG. 9 is a flowchart illustrating a driving method 900 of a touch display according to an embodiment of the present disclosure. Provided that the results are substantially the same, the steps shown in FIG. 9 are not required to be executed in the exact order. The method 900 is summarized as follow.
Step 902: determine if it is a biometric required scenario, if yes, go to step 822; otherwise, go to step 812.
Step 912: operate in a touch mode.
Step 914: transmit a transmitter signal to each transmitter electrode in a first section of a touch display panel.
Step 916: make a part of electrodes in a second section of the touch display panel short circuit, and transmit the transmitter signal to the part of the electrodes in the second section.

With such configurations, the part of the electrodes in the second section is configured as the transmitter electrode. Therefore, the touch maneuver of the user can be detected by sensing the mutual-capacitor formed between each transmitter electrode and the corresponding receiver electrode.
Step 922: operate in a biometric mode.
Step 924: transmit a transmitter signal to each transmitter electrode in the first section of the touch display panel
Step 926: couple each electrode in the second section of the touch display panel separately to a common voltage

With such configurations, the touch maneuver of the user can stilled be sensed by the first section while the biometric of the user such like the fingerprint can be sensed by the second section.

Those skilled in the art should readily understand the detail of the driving method 900 after reading the embodiments of FIGS. 6 and 7. The detailed description is omitted here for brevity.

What is claimed is:

1. A touch display, comprising:
a driver integrated circuit (IC), arranged to selectively control the touch display to operate in a touch mode or a biometric mode; and
a touch display panel, including:
a first section, including a plurality of first electrodes, wherein the first section is arranged to sense a touch maneuver of a user; and
a second section including a plurality of second electrodes, a bottom surface of the second section and a bottom surface of the first section are coplanar, wherein the second section is arranged to sense a biometric of the user when the touch display operates in the biometric mode, and sense the touch maneuver of the user when the touch display operates in the touch mode.

2. The touch display of claim 1, the plurality of first electrodes includes transmitter electrodes and receiver electrodes, and the driver IC is further arranged to transmit a first transmitter signal through each of the transmitter electrodes, and receive a first receiver signal through each receiver electrodes.

3. The touch display of claim 1, wherein the driver IC is further arranged to transmit a second transmitter signal through a part of the plurality of second electrodes coupled together while receive a second receiver signal through another part of the plurality of second electrodes coupled together when the touch display operates in the touch mode.

4. The touch display of claim 2, wherein the driver IC is further arranged to couple each of the plurality of second electrodes to a common voltage source when the touch display operates in the biometric mode.

5. The touch display of claim 2, wherein two of the receiver electrodes are coupled through a contact via.

6. The touch display of claim 2, wherein two of the transmitter electrodes are coupled through a contact via.

7. The touch display of claim 1, wherein the driver IC is arranged to couple each of the plurality of first electrodes to a common voltage source.

8. The touch display of claim 7, wherein the driver IC is further arranged to couple the plurality of the second electrodes together when the touch display operates in the touch mode.

9. The touch display of claim 7, wherein the driver IC is further arranged to couple each of the plurality of second electrodes to a common voltage source when the touch display operates in the fingerprint mode.

10. The touch display of claim 7, wherein each of the plurality of first electrodes is coupled to the common voltage source through a contact via.

11. A driver integrated circuit (IC) of a touch display, the touch display includes a touch display panel which includes a plurality of first electrodes and a plurality of second electrodes, a size of each second electrode is smaller than that of each first electrode, and bottom surfaces of the plurality of second electrodes and bottom surfaces of the plurality of first electrodes are coplanar, wherein the driver IC is arranged to couple each second electrode to a common voltage source when the touch display operates in a biometric mode to sense a biometric of a user.

12. The driver IC of claim 11, wherein the driver IC is further arranged to transmit a. transmitter signal through a part of the plurality of second electrodes and receive a receiver signal through another part of the plurality of second electrodes when the touch display operates in a touch mode to sense a touch maneuver of the user.

13. The driver IC of claim 11, wherein the driver IC is further arranged to couple the plurality of second electrodes together when the touch display operates in the touch mode.

14. A touch display panel, including:
an illuminate layer, formed on a substrate; and
a plurality of electrodes in a horizontally different tier from the illuminate layer; and
a circuit is electrically coupled to the electrodes and used to switch a portion of the electrodes between a mode for recognition to a touch maneuver of a user and a mode for recognition to a biometrics of the user.

15. The touch display panel of claim 14, wherein the plurality of electrodes are formed on a top surface of the illuminate layer.

16. The touch display panel of claim 14. further comprising:
a patterned cap layer provided on a top surface of the illuminate layer;
wherein bottom surfaces of the plurality of electrodes and a bottom surface of the patterned cap layer are coplanar.
